(19) United States
(12) Patent Application Publication
(10) Pub. No.: US 2025/0212611 A1
(43) Pub. Date: Jun. 26, 2025

(54) DISPLAY DEVICE AND METHOD OF FABRICATING THE DISPLAY DEVICE

(71) Applicant: Samsung Display Co., Ltd., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 18/759,995

(22) Filed: Jun. 30, 2024

(30) Foreign Application Priority Data
Dec. 20, 2023 (KR) 10-2023-0186925

(51) Int. Cl. H10K 59/122; H10K 59/12; H10K 59/131; H10K 59/80; H10K 71/60

(52) U.S. Cl. CPC H10K 59/122; H10K 59/1201; H10K 59/131; H10K 59/80516; H10K 59/873; H10K 71/60

(57) ABSTRACT

A display device includes: a substrate including a light emitting area and a non-light emitting area; a first anode electrode positioned on the light emitting area of the substrate; an auxiliary electrode positioned on the non-light emitting area of the substrate and spaced apart from the first anode electrode; a pixel defining layer positioned on the first anode electrode and the auxiliary electrode and defining a first opening; a first light emitting layer positioned on the first anode electrode and completely covering the pixel defining layer; a first cathode electrode positioned on the first light emitting layer; a bank structure positioned on the auxiliary electrode and defining a second opening, the bank structure including a first bank layer, a second bank layer, and a third bank layer which are sequentially stacked; and a first encapsulation layer positioned on the bank structure.

This application claims priority to Korean Patent Application No. 10-2023-0186925, filed on Dec. 20, 2023, and all the benefits accruing therefrom under 35 U.S.C. § 119, the content of which in its entirety is herein incorporated by reference.

### BACKGROUND

### 1. Technical Field

The present disclosure relates to a display device and a method of fabricating the display device.

### 2. Description of the Related Art

As the information society develops, the demand for display devices of various forms for displaying an image is increasing. For example, display devices have been applied to various electronic devices such as, for example, smartphones, digital cameras, laptop computers, navigation devices, and smart televisions. The display devices may be flat panel display devices such as, for example, liquid crystal display devices, field emission display devices, or organic light emitting display devices. Among the flat panel display devices, the light emitting display device may include a light emitting element in which each of the pixels of a display panel may emit light by itself, thereby displaying an image without a backlight unit providing the light to the display panel.

With the development of various electronic devices, the demand for high-resolution display devices is increasing. Since high-resolution display devices require high pixel integration, the spacing between light emitting elements overlapping each light emitting area may be narrowed. Accordingly, in some cases, a high-resolution display device may be formed by a pattern process of forming individual pixels rather than a mask process.

### SUMMARY

Aspects of the present disclosure provide a display device including cathode electrodes disposed to overlap each light emitting area and be spaced apart from each other, and a bank structure disposed to overlap a non-light emitting area. Aspects of the present disclosure are also to solve defective detachment caused by a decrease in adhesion between a bank structure and a cathode electrode, and external moisture permeation defects caused by detachment of the bank structure and the cathode electrode.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

In an embodiment of the disclosure, a display device includes a substrate including a light emitting area and a non-light emitting area; a first anode electrode positioned on the light emitting area of the substrate; an auxiliary electrode positioned on the non-light emitting area of the substrate and spaced apart from the first anode electrode; a pixel defining layer positioned on the first anode electrode and the auxiliary electrode and defining a first opening; a first light emitting layer positioned on the first anode electrode and completely covering the pixel defining layer; a first cathode electrode positioned on the first light emitting layer; a bank structure positioned on the auxiliary electrode and defining a second opening, the bank structure including a first bank layer, a second bank layer, and a third bank layer which are sequentially stacked; and a first encapsulation layer positioned on the bank structure, wherein a cavity is formed between the second bank layer and a first side surface of the first bank layer facing the light emitting area in a region overlapping the non-light emitting area, and in a region overlapping the cavity, the first cathode electrode is in contact with the auxiliary electrode, and the first light emitting layer does not overlap the cavity.

In an embodiment, the second bank layer may include a second side surface facing the light emitting area, and the second side surface protrudes further toward the light emitting area than the first side surface of the first bank layer.

In an embodiment, the third bank layer may include a tip that protrudes further toward the light emitting area than the second side surface of the second bank layer, and the protruding tip of the third bank layer and the second side surface form an undercut.

In an embodiment, a width of the cavity in a direction parallel to the substrate may be more than twice a height of the first bank layer.

In an embodiment, a height of the second bank layer may be more than twice the height of the first bank layer.

In an embodiment, the height of the first bank layer may range from 500 angstroms to 2000 angstroms.

In an embodiment, a material included in the first bank layer, a material included in the second bank layer, and a material included in the third bank layer may differ from one another.

In an embodiment, the first bank layer may include at least one of silicon nitride or aluminum, and the second bank layer may be silicon oxide.

In an embodiment, the display device may further comprise a residual electrode pattern positioned on a second side surface of the second bank layer, wherein the residual electrode pattern includes a same material as the first cathode electrode, and spaced apart from the first cathode electrode.

In an embodiment, the second side surface may include a first portion in contact with the residual electrode pattern and a second portion in contact with the first encapsulation layer, and the second side surface may be completely covered by the first portion and the second portion.

In an embodiment, an area of the second portion may be greater than an area of the first portion.

In an embodiment, the first encapsulation layer may be in contact with the first cathode electrode at a portion of the first cathode electrode overlapping the cavity.

In an embodiment, the display device may further comprise an organic pattern positioned on the third bank layer, wherein the organic pattern includes the same material as the first light emitting layer and is spaced apart from the first light emitting layer; and an electrode pattern positioned on the organic pattern, wherein the electrode pattern includes a same material as the first cathode electrode, and spaced apart from the first cathode electrode, wherein the electrode pattern and the residual electrode pattern may include a same material.

In an embodiment, the first encapsulation layer may be in contact with the organic pattern and the electrode pattern.

In an embodiment, the pixel defining layer may be completely covered by the first light emitting layer in a plan view, and the second opening completely surrounds the first opening in the plan view.

In an embodiment, the display device may further comprise a second anode electrode spaced apart from the first anode electrode with the auxiliary electrode interposed between the first anode electrode and the second anode electrode; a second light emitting layer on the second anode electrode; and a second cathode electrode on the second light emitting layer, wherein the auxiliary electrode includes a first side surface facing the bank structure, the first side surface of the auxiliary electrode includes a first portion in contact with the first cathode electrode, a second portion in contact with the second cathode electrode, and a third portion in contact with the first bank layer, and the first portion does not overlap the first light emitting layer, and the second portion may do not overlap the second light emitting layer.

In an embodiment, the first portion and the second portion may be spaced apart from each other with the third portion interposed between the first portion and the second portion, and the first cathode electrode and the second cathode electrode are electrically connected through the auxiliary electrode.

In an embodiment, the first encapsulation layer may include a first inorganic layer on the first cathode electrode and a second inorganic layer on the second cathode electrode, and in a direction perpendicular to the substrate, the first inorganic layer overlaps the first portion, and the second inorganic layer overlaps the second portion.

In an embodiment, the first inorganic layer and the second inorganic layer may be in contact with the second bank layer and the third bank layer, and the first inorganic layer and the second inorganic layer are spaced apart from each other in a region overlapping the non-light emitting area.

In an embodiment of the disclosure, a method of fabricating a display device, the method comprise forming a substrate including a light emitting area and a non-light emitting area, an anode electrode on the light emitting area of the substrate, and an auxiliary electrode on the non-light emitting area of the substrate, forming a pixel defining layer between the anode electrode and the auxiliary electrode, and forming a first bank material layer, a second bank material layer, and a third bank material layer entirely covering the auxiliary electrode and the pixel defining layer; forming a hole in a portion overlapping the anode electrode and forming the third bank material layer as a third bank layer by forming a photoresist while exposing the anode electrode and an overlapping portion around the anode electrode and removing the first bank material layer, the second bank material layer, and the third bank material layer in a portion where the photoresist is not formed through a first etching process; forming a first bank layer and a second bank layer so that a side surface of the second bank material layer protrudes more toward the hole than a side surface of the first bank material layer and the third bank layer has a tip that protrudes more toward the hole than the side surface of the second bank material layer, by partially etching the inside of the first bank material layer and the second bank material layer to overlap the hole through a second etching process; and forming an organic pattern, an electrode pattern, and a first inorganic layer positioned on the third bank layer and a light emitting element by forming a light emitting layer, a cathode electrode, and a first encapsulation layer on the anode electrode and the third bank layer, forming a hard mask on the anode electrode and an overlapping portion around the anode electrode, and removing the light emitting layer, the cathode electrode, and the first encapsulation layer positioned in a portion where the hard mask is not formed through an etching process, wherein in the forming of the first bank layer and the second bank layer, a cavity is formed between a side surface of the first bank layer facing the light emitting area and the second bank layer, and the cathode electrode is in contact with the auxiliary electrode in a portion overlapping the cavity.

The display device according to an embodiment includes a bank structure including a first bank layer, a second bank layer, and a third bank layer of the display device, and an auxiliary electrode connected to the first bank layer. Sidewalls of the first bank layer of an embodiment may be recessed on both sides more than sidewalls of the second bank layer to form an undercut with the second bank layer. Further, the third bank layer of an embodiment may have a tip that more protrudes toward the light emitting area than the sidewall of the second bank layer.

The display device of an embodiment may be formed such that the cathode electrode is in contact with the auxiliary electrode at a portion overlapping the undercut formed between the first bank layer and the second bank layer. Therefore, according to an embodiment, the cathode electrodes disposed to be spaced apart from each other in each light emitting area may be electrically connected through the auxiliary electrode.

As a result, according to the display device according to an embodiment, as the cathode electrodes disposed to overlap each light emitting area and be spaced apart from each other and the bank structure disposed to overlap the non-light emitting area may be formed, and the cathode electrode is formed to be electrically connected to the auxiliary electrode, moisture permeation defects in the display device caused by detachment of the cathode electrode and the bank structure may be solved.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating an electronic device according to an embodiment;

FIG. 2 is a perspective view illustrating a display device included in the electronic device according to an embodiment;

FIG. 3 is a schematic cross-sectional view of the display device of FIG. 2;

FIG. 4 is a plan view illustrating an arrangement of light emitting areas in a display area of FIG. 3;

FIG. 5 is a cross-sectional view of a display area taken along line X1-X1′ of FIG. 4;

FIG. 6 is an enlarged cross-sectional view of a first light emitting area of FIG. 5;

FIG. 7 is a schematic plan view illustrating the first light emitting area of FIG. 6;

FIG. 8 is an enlarged cross-sectional view of a non-light emitting area disposed between a first light emitting area and a second light emitting area of FIG. 5;

FIG. 9 is an enlarged cross-sectional view of a bank structure of FIG. 8; and

FIGS. 10 to 21 are cross-sectional views schematically illustrating a method of fabricating a display element layer and a thin film encapsulation layer included in the display device of FIG. 5.

### DETAILED DESCRIPTION

The invention now will be described more fully hereinafter with reference to the accompanying drawings, in which various embodiments are illustrated. Aspects supported by the present disclosure may, however, be embodied in many different forms, and should not be construed as limited to the embodiments set forth herein. Rather, the example embodiments are provided such that this disclosure will be thorough and complete, and will fully convey the scope of example aspects of the present disclosure to those skilled in the art. Like reference numerals refer to like elements throughout.

It will be understood that when an element is referred to as being “on” another element, the element can be directly on the other element or intervening elements may be present between the element and the other element. In contrast, when an element is referred to as being “directly on” another element, there are no intervening elements present.

It will be understood that, although the terms “first,” “second,” “third,” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

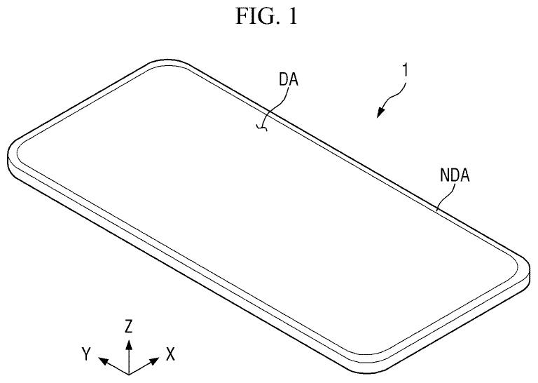

FIG. 1 is a schematic perspective view of an electronic device 1 according to an embodiment.

Referring to FIG. 1, an electronic device 1 displays a moving image or a still image. The electronic device 1 may refer to any electronic device that provides a display screen. For example, electronic device 1 may include televisions, laptop computers, monitors, billboards, Internet of things, mobile phones, smartphones, tablet personal computers (PCs), electronic watches, smartwatches, watch phones, head mounted displays, mobile communication terminals, electronic notebooks, electronic books, portable multimedia players (PMPs), navigation, game consoles, digital cameras, camcorders, and the like that provide the display screen.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) means a horizontal direction in the drawings, the second direction (Y-axis direction) means a vertical direction in the drawings, and the third direction (Z-axis direction) means upper and lower directions in the drawings, that is, a thickness direction. In the following specification, unless otherwise specified, the term “direction” may refer to both directions toward both sides extending along the direction. In some aspects, when both “directions” extending to both sides are to be distinguished from each other, one side will be referred to as “one side in the direction” and the other side will be referred to as “the other side in the direction”. In FIG. 1, a direction in which an arrow indicating a direction is directed is referred to as one side, and an opposite direction thereof is referred to as the other side.

Hereinafter, for convenience of explanation, in referring to surfaces of the electronic device 1 or each member constituting the electronic device 1, one surface facing one side in a direction in which an image is displayed, that is, in the third direction (Z-axis direction) is referred to as an upper surface, and an opposite surface of the one surface is referred to as the other surface. However, embodiments of the present disclosure are not limited thereto, and the one surface and the other surface of the member may be referred to as a front surface and a rear surface, respectively, or may also be referred to as a first surface or a second surface. In some aspects, in describing a relative position of each member of the electronic device 1, one side in the third direction (Z-axis direction) may be referred to as an upper side and the other side in the third direction (Z-axis direction) may be referred to as a lower side.

A shape of the electronic device 1 may be variously changed. For example, the electronic device 1 may have a shape such as, for example, a rectangle with a long width, a rectangle with a long length, a square, a quadrangle with rounded corners (vertices), other polygons, or a circle.

The electronic device 1 may include a display area DA and a non-display area NDA. The display area DA is an area in which a screen may be displayed, and the non-display area NDA is an area in which a screen is not displayed. The display area DA may also be referred to as an active area, and the non-display area NDA may also be referred to as a non-active area. The display area DA may generally occupy the center of the electronic device 1.

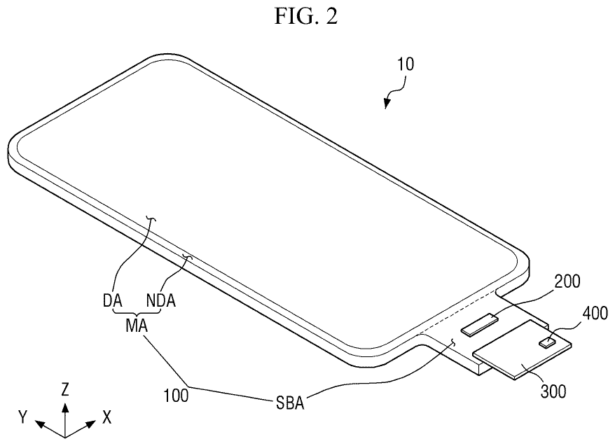

FIG. 2 is a perspective view illustrating a display device 10 included in the electronic device 1 according to an embodiment.

Referring to FIG. 2, the electronic device 1 according to an embodiment may include a display device 10. The display device 10 may provide a screen displayed by the electronic device 1. Examples of the display device 10 may include an inorganic light emitting diode display device, an organic light emitting display device, a quantum dot light emitting display device, a plasma display device, and a field emission display device. Hereinafter, it is illustrated that an organic light emitting diode display device is used as an example of the display device, but embodiments of the present disclosure are not limited thereto and may also be applied to other display devices as long as the same technical idea is applicable thereto.

The display device 10 may have a planar shape similar to the shape of the electronic device 1. For example, the display device 10 may have a rectangular shape having a short side in a first direction (X-axis direction) and a long side in a second direction (Y-axis direction). A corner where the short side in the first direction (X-axis direction) and the long side in the second direction (Y-axis direction) meet may be rounded to have a curvature, but is not limited thereto and may also be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA. The main area MA may include a display area DA including pixels displaying an image, and a non-display area NDA disposed around the display area DA.

The display area DA may emit light from a plurality of light emitting areas or a plurality of openings to be described later. For example, the display panel 100 may include a pixel circuit including switching elements, a pixel defining layer defining the light emitting areas or the openings, and a self-light emitting element. For example, the self-light emitting element may include, but is not limited to, at least one of an organic light emitting diode (LED) including an organic light emitting layer, a quantum dot LED including a quantum dot light emitting layer, an inorganic LED including an inorganic semiconductor, and a micro LED. In the following drawings, it is illustrated that the self-light emitting element is an organic light emitting diode.

The non-display area NDA may be an area outside the display area DA. The non-display area NDA may be defined as an edge area of the main area MA of the display panel 100.

The sub-area SBA may be an area extending from one side of the main area MA. The sub-area SBA may include a flexible material that may be bent, folded, rolled, or the like. In an example in which the sub-area SBA is bent, the sub-area SBA may overlap the main area MA in a thickness direction (e.g., a third direction (Z-axis direction)). The sub-area SBA may include the display driver 200 and a pad portion connected to the circuit board 300. In another embodiment, the sub-area SBA may be omitted, and the display driver 200 and the pad portion may be positioned in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the pad portion of the display panel 100 using an anisotropic conductive film (ACF). The circuit board 300 may be a flexible film such as, for example, a flexible printed circuit board, a printed circuit board, or a chip on film.

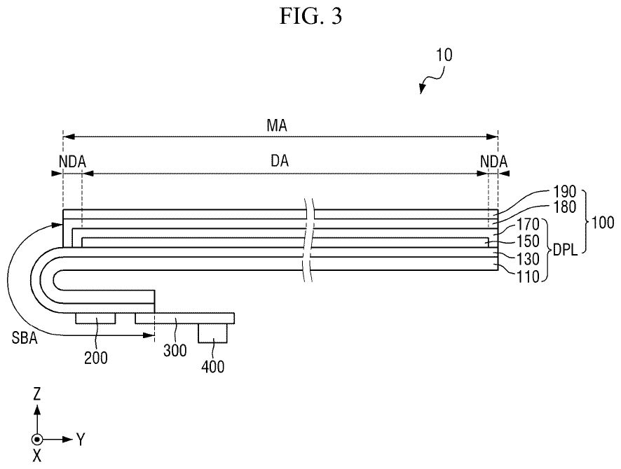

The touch driver 400 may be mounted on the circuit board 300. The touch driver 400 may be connected to a touch sensor layer (“180” in FIG. 3) of the display panel 100. The touch driver 400 may be formed as an integrated circuit.

FIG. 3 is a schematic cross-sectional view of the display device 10 of FIG. 2.

Referring to FIG. 3, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, rolled, or the like. For example, the substrate 110 may include a polymer resin such as, for example, polyimide PI, but is not limited thereto. In another embodiment, the substrate 110 may include a glass material or a metal material.

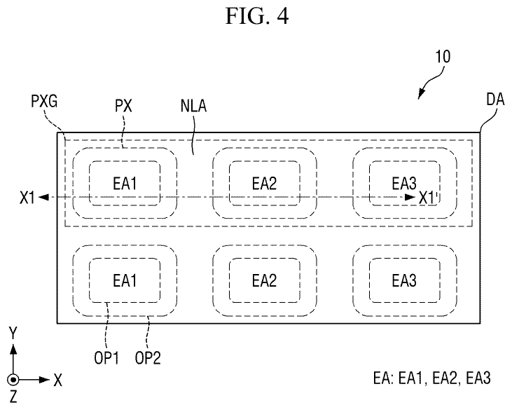

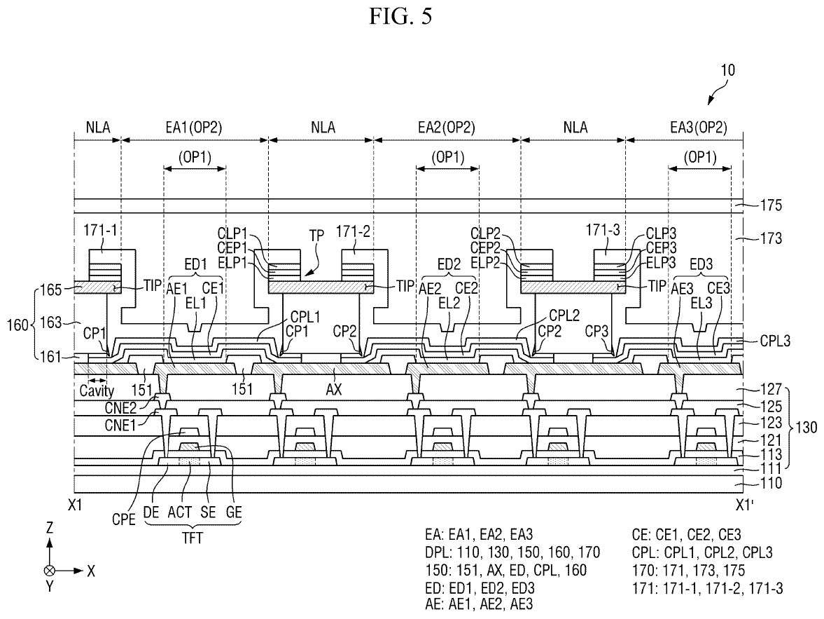

The thin film transistor layer 130 may be disposed on the substrate 110. The thin film transistor layer 130 may be disposed in the display area DA, the non-display area NDA, and the sub-area SBA. The thin film transistor layer 130 may include a plurality of thin film transistors (“TFT” in FIG. 5) constituting a pixel (“PX” in FIG. 4).

The display element layer 150 may be disposed on the thin film transistor layer 130. The display element layer 150 may be positioned to overlap the display area DA. The display element layer 150 may include a plurality of light emitting elements (“ED” in FIG. 5). As an example, the display element according to an embodiment may include, but is not limited to, at least one of an organic light emitting diode (LED) including an organic light emitting layer, a quantum dot LED including a quantum dot light emitting layer, an inorganic LED including an inorganic semiconductor, and a micro LED.

The thin film encapsulation layer 170 may be positioned on the display element layer 150. The thin film encapsulation layer 170 may be positioned to overlap the display area DA and the non-display area NDA. The thin film encapsulation layer 170 may cover an upper surface and side surfaces of the display element layer 150, and may protect the display element layer 150 from external oxygen and moisture. The thin film encapsulation layer 170 may include at least one inorganic film and at least one organic film for encapsulating the display element layer 150.

The touch sensor layer 180 may be disposed on the thin film encapsulation layer 170. The touch sensor layer 180 may be positioned to overlap the display area DA and the non-display area NDA. The touch sensor layer 180 may sense a user's touch in a mutual capacitance method or a self-capacitance method.

The color filter layer 190 may be disposed on the touch sensor layer 180. The color filter layer 190 may be positioned to overlap the display area DA and the non-display area NDA. The color filter layer 190 may absorb a portion of light introduced from the outside of the display device 10 to reduce reflected light caused by external light. Therefore, the color filter layer 190 may prevent color distortion caused by reflection of external light.

As the color filter layer 190 is directly disposed on the touch sensor layer 180, the display device 10 may be implemented without a separate substrate for the color filter layer 190. Therefore, the display device 10 may have a relatively small thickness. In some aspects, the color filter layer 190 may also be omitted depending on the embodiment.

As illustrated in FIG. 3, a portion of the display layer DPL overlapping the sub-area SBA may be bent. In an example in which a portion of the display layer DPL is bent, the display driver 200, circuit board 300, and touch driver 400 may overlap the main area MA in the third direction (Z-axis direction).

FIG. 4 is a plan view illustrating an arrangement of light emitting areas EA in the display area DA of FIG. 3.

Referring to FIG. 4, the display area DA according to an embodiment may include a plurality of first to third light emitting areas EA1, EA2, and EA3 and a non-light emitting area NLA. The non-light emitting area NLA may be positioned to surround the plurality of first to third light emitting areas EA1, EA2, and EA3.

The non-light emitting area NLA may block each light emitted from the plurality of first to third light emitting areas EA1, EA2, and EA3. As a result, the non-light emitting area NLA may assist in preventing each light emitted from the first to third light emitting areas EA1, EA2, and EA3 from being mixed.

The light emitting areas EA may include a first light emitting area EA1, a second light emitting area EA2, and a third light emitting area EA3 that emit light of different colors. Each of the first to third light emitting areas EA1, EA2, and EA3 may each emit red, green, or blue light, and the color of light emitted from each of the first to third light emitting areas EA1, EA2, and EA3 may vary depending on the type of light emitting element ED, which will be described later. In an embodiment, the first light emitting area EA1 may emit red light of a first color, the second light emitting area EA2 may emit green light of a second color, and the third light emitting area EA3 may emit blue light of a third color, but embodiments of the present disclosure are not limited thereto. It is illustrated in the drawing that the size and shape of each of the first to third light emitting areas EA1, EA2, and EA3 are the same, but embodiments of the present disclosure are not limited thereto. The size and shape of each of the first to third light emitting areas EA1, EA2, and EA3 may be freely adjusted according to required characteristics.

The plurality of first to third light emitting areas EA1, EA2, and EA3 may be defined by a first opening OP1 and a second opening OP2. As an example, the first opening OP1 may be defined by a pixel defining layer 151, which will be described later, and the second opening OP2 may be defined by a bank structure 160, which will be described later. In the plan view, the second opening OP2 may completely surround the first opening OP1, and the second opening OP2 may be completely surrounded by the non-light emitting area NLA. Details will be described later.

In some embodiments, at least one first light emitting area EA1, at least one second light emitting area EA2, and at least one third light emitting area EA3 disposed to be adjacent to each other may form one pixel group PXG. The pixel group PXG may be a minimum unit that emits white light. However, the type and/or number of the first to third light emitting areas EA1, EA2, and EA3 constituting the pixel group PXG may vary depending on the embodiments.

FIG. 5 is a schematic cross-sectional view of the display area DA taken along line X1-X1′ of FIG. 4. FIG. 5 is a partial cross-sectional view of the display device 10 overlapping the display area DA and illustrates a schematic cross-section of the display layer DPL. That is, FIG. 5 illustrates a cross section of the substrate 110, the thin film transistor layer 130, the display element layer 150, and the thin film encapsulation layer 170 of the display device 10 according to an embodiment. Since the substrate 110 was described with reference to FIG. 3, a description thereof will be omitted.

Referring to FIG. 5, the thin film transistor layer 130 may be positioned on the substrate 110. The thin film transistor layer 130 may include a first buffer layer 111, a thin film transistor TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be disposed on the substrate 110. The first buffer layer 111 may include an inorganic film capable of preventing permeation of air or moisture. For example, the first buffer layer 111 may include a plurality of inorganic films alternately stacked.

The thin film transistor TFT may be disposed on the first buffer layer 111, and may constitute a pixel circuit connected to each of the plurality of pixels. As an example, the thin film transistor TFT may be a driving transistor or a switching transistor of the pixel circuit. The thin film transistor TFT may include an active layer ACT, a source electrode SE, a drain electrode DE, and a gate electrode GE.

The active layer ACT may be disposed on the first buffer layer 111. The active layer ACT may overlap the gate electrode GE in the third direction (Z-axis direction), and may be insulated from the gate electrode GE by the gate insulating layer 113. In a portion of the active layer ACT, a material of the active layer ACT may become a conductor to form the source electrode SE and the drain electrode DE.

The gate electrode GE may be disposed on the gate insulating layer 113. The gate electrode GE may overlap the active layer ACT with the gate insulating layer 113 interposed between the gate electrode GE and the active layer ACT.

The gate insulating layer 113 may be disposed on the active layer ACT. The gate insulating layer 113 may cover the active layer ACT and the first buffer layer 111, and may insulate the active layer ACT and the gate electrode GE from each other. The gate insulating layer 113 may include a contact hole through which the first connection electrode CNE1 penetrates.

The first interlayer insulating layer 121 may cover the gate electrode GE and the gate insulating layer 113. The first interlayer insulating layer 121 may include a contact hole through which the first connection electrode CNE1 penetrates. The contact hole of the first interlayer insulating layer 121 may be connected to the contact hole of the gate insulating layer 113 and a contact hole of the second interlayer insulating layer 123.

The capacitor electrode CPE may be disposed on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode CNE1 penetrates. The contact hole of the second interlayer insulating layer 123 may be connected to the contact hole of the first interlayer insulating layer 121 and the contact hole of the gate insulating layer 113.

The first connection electrode CNE1 may be disposed on the second interlayer insulating layer 123. The first connection electrode CNE1 may electrically connect the drain electrode DE of the thin film transistor TFT and the second connection electrode CNE2 to each other. The first connection electrode CNE1 may be inserted into the contact holes formed in the first interlayer insulating layer 121, the second interlayer insulating layer 123, and the gate insulating layer 113 and be in contact with the drain electrode DE of the thin film transistor TFT.

The first via layer 125 may cover the first connection electrode CNE1 and the second interlayer insulating layer 123. The first via layer 125 may planarize a lower structure. The first via layer 125 may include a contact hole through which the second connection electrode CNE2 penetrates.

The second connection electrode CNE2 may be disposed on the first via layer 125. The second connection electrode CNE2 may be inserted into the contact hole formed in the first via layer 125 and be in contact with the first connection electrode CNE1. The second connection electrode CNE2 may electrically connect the first connection electrode CNE1 and first to third anode electrodes AE1, AE2, and AE3 to each other.

The second via layer 127 may cover the second connection electrode CNE2 and the first via layer 125. The second via layer 127 may include a contact hole through which the first to third anode electrodes AE1, AE2, and AE3 penetrate.

The display element layer 150 may be disposed on the second via layer 127. The display element layer 150 may include a pixel defining layer 151, an auxiliary electrode AX, a light emitting element ED, a capping layer CPL, and a bank structure 160.

The light emitting element ED according to an embodiment may include a first light emitting element ED1 disposed in a portion overlapping the first light emitting area EA1, a second light emitting element ED2 disposed in a portion overlapping the second light emitting area EA2, and a third light emitting element ED3 disposed in a portion overlapping the third light emitting area EA3. The first light emitting element ED1 may include a first anode electrode AE1, a first light emitting layer EL1, and a first cathode electrode CE1, the second light emitting element ED2 may include a second anode electrode AE2, a second light emitting layer EL2, and a second cathode electrode CE2, and the third light emitting element ED3 may include a third anode electrode AE3, a third light emitting layer EL3, and a third cathode electrode CE3. Each of the first to third light emitting elements ED1, ED2, and ED3 may emit light of different colors depending on the material of the first to third light emitting layers EL1, EL2, and EL3. For example, the first light emitting element ED1 may emit red light of a first color, the second light emitting element ED2 may emit green light of a second color, and the third light emitting element ED3 may emit blue light of a third color.

The anode electrode AE according to an embodiment may be disposed on the second via layer 127. The anode electrode AE may be electrically connected to the drain electrode DE of the thin film transistor TFT through the first and second connection electrodes CNE1 and CNE2. The anode electrode AE according to an embodiment may include a first anode electrode AE1 disposed in the first light emitting area EA1, a second anode electrode AE2 disposed in the second light emitting area EA2, and a third anode electrode AE3 disposed in the third light emitting area EA3. The first anode electrode AE1, the second anode electrode AE2, and the third anode electrode AE3 may be disposed such that the first anode electrode AE1, the second anode electrode AE2, and the third anode electrode AE3 are spaced apart from each other with the auxiliary electrode AX interposed therebetween. For example, an auxiliary electrode AX may be interposed between the first anode electrode AE1 and the second anode electrode AE2, and an auxiliary electrode AX may be interposed between the second anode electrode AE2 and the third anode electrode AE3.

As an example, the anode electrode AE may have a stacked film structure in which a material layer having a high work function, formed of indium tin oxide (ITO), indium zinc oxide (IZO), zinc oxide (ZnO), or indium oxide (In₂O₃) and a reflective material layer formed of silver (Ag), magnesium (Mg), aluminum (Al), platinum (Pt), lead (Pd), palladium (Pd), gold (Au), nickel (Ni), neodymium (Nd), iridium (Ir), chromium (Cr), lithium (Li), calcium (Ca), or mixtures thereof are stacked. As an example, the first to third anode electrodes AE1, AE2, and AE3 may have a multi-layer structure of ITO/Mg, ITO/MgF, ITO/Ag, and ITO/Ag/ITO, but are not limited thereto.

The auxiliary electrode AX according to an embodiment may be disposed on the second via layer 127. The auxiliary electrode AX may be disposed to overlap the light emitting area EA and the non-light emitting area NLA. The auxiliary electrode AX may be electrically connected to the drain electrode DE of the thin film transistor TFT through the first and second connection electrodes CNE1 and CNE2. The auxiliary electrode AX may be spaced apart from the first to third anode electrodes AE1, AE2, and AE3 in the first direction (X-axis direction) with the pixel defining layer 151 interposed therebetween. For example, the pixel defining layer 151 may be interposed between an auxiliary electrode AX and the first anode electrode AE1, between the auxiliary electrode AX and the second anode electrode AE2, between another auxiliary electrode AX and the second anode electrode AE2, and between the other auxiliary electrode AX and the third anode electrode AE3.

The auxiliary electrode AX according to an embodiment may include the same metal as the anode electrode AE or a metal that has a low contact resistance with the cathode electrode CE according to an embodiment. In an embodiment, when the auxiliary electrode AX includes the same material as the anode electrode AE, this may facilitate processes described herein of forming the auxiliary electrode AX. The material of the anode electrode AE has already been mentioned and will be thus omitted. In another embodiment, when the auxiliary electrode AX is formed of molybdenum (Mo), this may minimize contact resistance with the cathode electrode CE of the display device 10. However, molybdenum (Mo) is an example, and the auxiliary electrode AX according to an embodiment may include any metal that has a low contact resistance with the cathode electrode CE according to an embodiment.

The pixel defining layer 151 according to an embodiment may be positioned on the second via layer 127, the anode electrode AE, and the auxiliary electrode AX. The pixel defining layer 151 according to an embodiment may be positioned between the anode electrode AE and the auxiliary electrode AX in the first direction (X-axis direction) in a portion overlapping the light emitting area EA, and may thereby separate and insulate the anode electrode AE and the auxiliary electrode AX from each other. In a portion overlapping each of the first to third light emitting areas EA1, EA2, and EA3, a plurality of pixel defining layers 151 adjacent to each other may define the first opening OP1, and may expose the anode electrode AE in a portion overlapping the first opening OP1.

The pixel defining layer 151 according to an embodiment may include an inorganic insulating material. As an example, the pixel defining layer 151 may include aluminum oxide, titanium oxide, tantalum oxide, hafnium oxide, zinc oxide, silicon oxide, silicon nitride, and silicon oxynitride.

The bank structure 160 according to an embodiment may be positioned on the auxiliary electrode AX in a portion overlapping the non-light emitting area NLA. The bank structure 160 according to an embodiment may define a second opening OP2, and the light emitting area EA according to an embodiment may be defined by the second opening OP2.

The bank structure 160 according to an embodiment may include a first bank layer 161, a second bank layer 163, and a third bank layer 165. The first bank layer 161, the second bank layer 163, and the third bank layer 165 may include different materials. For example, a material included the first bank layer 161 may differ from a material included in the second bank layer 163 or a material included in the third bank layer 165, and the material included the second bank layer 163 may differ from the material included in the third bank layer 165, which may support different respective characteristics (e.g., etching rates) of the first bank layer 161, the second bank layer 163, and the third bank layer 165. A cavity may be formed between the first bank layer 161 and the second bank layer 163 according to an embodiment. In some aspects, the third bank layer 165 according to an embodiment may have a tip that protrudes further toward the light emitting area EA than the second bank layer 163. Details on the bank structure 160 will be described later.

The light emitting layer EL according to an embodiment may be disposed on the anode electrode AE and the pixel defining layer 151. In the light emitting layer EL according to an embodiment, when the thin film transistor TFT applies a predetermined voltage to the anode electrode AE and the cathode electrode CE receives a common voltage or a cathode voltage, each of the holes and electrons may move to the light emitting layer EL through the hole transporting layer and the electron transporting layer, and the holes and electrons may be combined with each other in the light emitting layer EL to emit light.

The light emitting layers EL according to an embodiment may be spaced apart from each other at a portion overlapping each of the first to third light emitting areas EA1, EA2, and EA3. The first light emitting layer EL1 may be disposed in a portion overlapping the first light emitting area EA1, the second light emitting layer EL2 may be disposed in a portion overlapping the second light emitting area EA2, and the third light emitting layer EL3 may be disposed in a portion overlapping the third light emitting area EA3. As an example, the first light emitting layer EL1 may be a light emitting layer that emits red light of a first color, the second light emitting layer EL2 may be a light emitting layer that emits green light of a second color, and the third light emitting layer EL3 may be a light emitting layer that emits blue light of a third color, but embodiments of the present disclosure are not limited thereto.

The light emitting layer EL according to an embodiment may be an organic light emitting layer formed of an organic material, and may be formed through a deposition process and a photo pattern process without a fine metal mask in the fabricating process. The fabricating process will be described later.

The cathode electrode CE according to an embodiment may be disposed on the light emitting layer EL. The cathode electrode CE may include a transparent conductive material such that light generated in the light emitting layer EL may be emitted. The cathode electrode CE may receive a common voltage or a low potential voltage. In the case in which the anode electrode AE receives a voltage corresponding to the data voltage and the cathode electrode CE receives the low potential voltage, as a potential difference is formed between the anode electrode AE and the cathode electrode CE, the light emitting layer EL may emit light.

The cathode electrode CE according to an embodiment may include a material layer having a small work function, such as, for example, Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg, or the like). The cathode electrode CE may further include a transparent metal oxide layer disposed on the material layer having the small work function.

The cathode electrodes CE according to an embodiment may be spaced apart from each other at a portion overlapping each of the first to third light emitting areas EA1, EA2, and EA3. The first cathode electrode CE1 may be disposed on the first light emitting layer EL1 in the first light emitting area EA1, the second cathode electrode CE2 may be disposed on the second light emitting layer EL2 in the second light emitting area EA2, and the third cathode electrode CE3 may be disposed on the third light emitting layer EL3 in the third light emitting area EA3. The first to third cathode electrodes CE1, CE2, and CE3 spaced apart from each other at a portion overlapping each of the first to third light emitting areas EA1, EA2, and EA3 may be electrically connected to each other by the auxiliary electrode AX.

The cathode electrode CE according to an embodiment may be formed through a deposition process and a photo pattern process without a fine metal mask during the fabricating process. The fabricating process will be described later.

The capping layer CPL according to an embodiment may be disposed on the cathode electrode CE. The capping layer CPL may include an inorganic insulating material to prevent the patterns disposed on the plurality of light emitting elements ED and the third bank layer 165 from being damaged from external air, and to prevent the patterns disposed on the plurality of light emitting elements ED and the bank structure 160 from being peeled off during the process of fabricating the display device 10.

The capping layer CPL according to an embodiment may include an inorganic insulating material. As an example, the capping layer CPL according to an embodiment may include aluminum oxide, titanium oxide, tantalum oxide, hafnium oxide, zinc oxide, silicon oxide, silicon nitride, and silicon oxynitride.

The capping layers CPL according to an embodiment may be spaced apart from each other at a portion overlapping each of the first to third light emitting areas EA1, EA2, and EA3. A first capping layer CPL1 may be disposed on the first cathode electrode CE1 in a portion overlapping the first light emitting area EA1, a second capping layer CPL2 may be disposed on the second cathode electrode CE2 in a portion overlapping the second light emitting area EA2, and a third capping layer CPL3 may be disposed on the third cathode electrode CE3 in a portion overlapping the third light emitting area EA3.

A plurality of first to third organic patterns ELP1, ELP2, and ELP3, first to third electrode patterns CEP1, CEP2, and CEP3, and first to third capping patterns CLP1, CLP2, and CLP3 may be disposed on the bank structure 160 according to an embodiment to surround the second opening OP2.

The plurality of first to third organic patterns ELP1, ELP2, and ELP3 may be positioned on the third bank layer 165. The first to third organic patterns ELP1, ELP2, and ELP3 may include the same material as the first to third light emitting layers EL1, EL2, and EL3, respectively. The first organic pattern ELP1 may include the same material as the first light emitting layer EL1, the second organic pattern ELP2 may include the same material as the second light emitting layer EL2, and the third organic pattern ELP3 may include the same material as the third light emitting layer EL3.

As described herein, the light emitting layer EL according to an embodiment may be formed through the deposition and photo pattern process without using the separate fine metal mask in the process of fabricating the display device 10. As a result, during the process of fabricating the display device 10, the material forming the light emitting layer EL may be deposited on the anode electrode AE and also on the third bank layer 165. The first to third organic patterns ELP1, ELP2, and ELP3 according to an embodiment may be traces formed when the material of the light emitting layer EL deposited on the third bank layer 165 is not connected to the light emitting layer EL deposited on the anode electrode AE and is disconnected, as the third bank layer 165 includes the tip.

In the portion overlapping the non-light emitting area NLA, the first to third organic patterns ELP1, ELP2, and ELP3 may be disposed such that the first to third organic patterns ELP1, ELP2, and ELP3 are spaced apart from each other in the first direction (X-axis direction). A second encapsulation layer 173 may be disposed between the first to third organic patterns ELP1, ELP2, and ELP3 spaced apart from each other. The first to third organic patterns ELP1, ELP2, and ELP3 according to an embodiment may be formed to entirely cover the third bank layer 165 during the process of fabricating the display device 10, and portions of the first to third organic patterns ELP1, ELP2, and ELP3 that overlap the non-light emitting area NLA may be then removed through a subsequent etching process. Therefore, the first to third organic patterns ELP1, ELP2, and ELP3 may include a trench portion TP in a portion overlapping the non-light emitting area NLA. The fabricating process will be described later.

The plurality of first to third electrode patterns CEP1, CEP2, and CEP3 may be disposed on the first to third organic patterns ELP1, ELP2, and ELP3, respectively. For example, the first electrode pattern CEP1, the second electrode pattern CEP2, and the third electrode pattern CEP3 may be directly disposed on the first organic pattern ELP1, the second organic pattern ELP2, and the third organic pattern ELP3, respectively. An arrangement relationship between the first to third electrode patterns CEP1, CEP2, and CEP3 and the first to third organic patterns ELP1, ELP2, and ELP3 may be the same as the arrangement relationship between the first to third light emitting layers EL1, EL2, and EL3 and the first to third cathode electrodes CE1, CE2, and CE3. The first to third electrode patterns CEP1, CEP2, and CEP3 may include the same material as the first to third cathode electrodes CE1, CE2, and CE3, respectively.

As described herein, the cathode electrode CE according to an embodiment may be formed through the deposition and photo pattern process without using the separate fine metal mask in the process of fabricating the display device 10. Therefore, during the process of fabricating the display device 10, the material forming the cathode electrode CE may be deposited on the anode electrode AE and also on the third bank layer 165. The first to third electrode patterns CEP1, CEP2, and CEP3 according to an embodiment may be traces formed when the material of the cathode electrode CE deposited on the third bank layer 165 is not connected to the material of the cathode electrode CE deposited on the anode electrode AE and is disconnected, as the third bank layer 165 includes the tip.

The deposition process of forming the cathode electrode CE according to an embodiment may have a higher step coverage than the deposition process of forming the light emitting layer EL and the deposition process of forming the capping layer CPL. Therefore, during the process of fabricating the display device 10, the material forming the cathode electrode CE may also be deposited on a side surface of the second bank layer 163 disposed toward the light emitting area EA. As a result, the second bank layer 163 according to an embodiment may further include first to third residual electrode patterns CP1, CP2, and CP3 on the side surface facing the light emitting area EA.

In the portion overlapping the non-light emitting area NLA, the first to third electrode patterns CEP1, CEP2, and CEP3 may be disposed such that the first to third electrode patterns CEP1, CEP2, and CEP3 are spaced apart from each other in the first direction (X-axis direction), and the second encapsulation layer 173 may be disposed between the first to third electrode patterns CEP1, CEP2, and CEP3 spaced apart from each other. The first to third electrode patterns CEP1, CEP2, and CEP3 according to an embodiment may be formed to entirely cover the third bank layer 165 during the process of fabricating the display device 10, and portions of the first to third electrode patterns CEP1, CEP2, and CEP3 may be then removed through a subsequent etching process. Therefore, the first to third electrode patterns CEP1, CEP2, and CEP3 may include a trench portion TP in the portion overlapping the non-light emitting area NLA. The fabricating process will be described later.

The plurality of first to third capping patterns CLP1, CLP2, and CLP3 may be positioned on the plurality of first to third electrode patterns CEP1, CEP2, and CEP3. The plurality of first to third capping patterns CLP1, CLP2, and CLP3 may include the same material as the first to third capping layers CPL1, CPL2, and CPL3, respectively. An arrangement relationship between the first to third capping patterns CLP1, CLP2, and CLP3 and the plurality of first to third electrode patterns CEP1, CEP2, and CEP3 may be the same as the arrangement relationship between the first to third capping layers CPL1, CPL2, and CPL3 and the first to third cathode electrodes CE1, CE2, and CE3.

The capping layer CPL according to an embodiment may be formed through the deposition and photo pattern process without using a separate fine metal mask in the process of fabricating the display device 10. Therefore, during the process of fabricating the display device 10, the material forming the capping layer CPL may be deposited on the anode electrode AE and also on the third bank layer 165. The first to third capping patterns CLP1, CLP2, and CLP3 according to an embodiment may be traces formed when the material of the capping layer CPL deposited on the third bank layer 165 is not connected to the capping layer CPL deposited on the anode electrode AE and is disconnected, as the third bank layer 165 includes the tip.

In the portion overlapping the non-light emitting area NLA, the first to third capping patterns CLP1, CLP2, and CLP3 may be disposed such that the first to third capping patterns CLP1, CLP2, and CLP3 are spaced apart from each other in the first direction (X-axis direction). The second encapsulation layer 173 may be disposed between the first to third capping patterns CLP1, CLP2, and CLP3 spaced apart from each other. The first to third capping patterns CLP1, CLP2, and CLP3 according to an embodiment may be formed to entirely cover the third bank layer 165 during the process of fabricating the display device 10, and portions of the first to third capping patterns CLP1, CLP2, and CLP3 may be then removed through a subsequent etching process. Therefore, the first to third capping patterns CLP1, CLP2, and CLP3 may include a trench portion TP in the portion overlapping the non-light emitting area NLA. The fabricating process will be described later.

The thin film encapsulation layer 170 may be positioned on the display element layer 150. The thin film encapsulation layer 170 includes at least one inorganic film to prevent oxygen or moisture from permeating into the display element layer 150. The thin film encapsulation layer 170 may include at least one organic film to protect the display element layer 150 from foreign substances such as, for example, dust. The thin film encapsulation layer 170 may include a first encapsulation layer 171, a second encapsulation layer 173, and a third encapsulation layer 175 that are sequentially stacked.

The first encapsulation layer 171 according to an embodiment may be disposed on the first to third capping layers CPL1, CPL2, and CPL3 and the first to third capping patterns CLP1, CLP2, and CLP3. Since the first encapsulation layer 171 according to an embodiment may be formed through a chemical vapor deposition (CVD) process, the first encapsulation layer 171 may be formed to have a uniform thickness along a profile of a lower structure.

The first encapsulation layer 171 may include one or more inorganic insulating materials. As an example, the first encapsulation layer 171 may include one or more of aluminum oxide, titanium oxide, tantalum oxide, hafnium oxide, zinc oxide, silicon oxide, silicon nitride, and silicon oxynitride.

The first encapsulation layer 171 according to an embodiment may include first to third inorganic layers 171-1, 171-2, and 171-3. The first to third inorganic layers 171-1, 171-2, and 171-3 may be positioned to overlap the first to third light emitting areas EA1, EA2, and EA3, respectively. As an example, the first inorganic layer 171-1 may overlap the first light emitting area EA1 and cover the first capping layer CPL1 and the first capping pattern CLP1. In some aspects, the second inorganic layer 171-2 may overlap the second light emitting area EA2 and cover the second capping layer CPL2 and the second capping pattern CLP2. In some aspects, the third inorganic layer 171-3 may overlap the third light emitting area EA3 and cover the third capping layer CPL3 and the third capping pattern CLP3.

It is illustrated in the drawing that the first to third inorganic layers 171-1, 171-2, and 171-3 are formed in the same layer, but the first to third inorganic layers 171-1, 171-2, and 171-3 may be formed in different processes. For example, the first inorganic layer 171-1 may be formed after forming the first cathode electrode CE1, the second inorganic layer 171-2 may be formed after forming the second cathode electrode CE2, and the third inorganic layer 171-3 may be formed after forming the third cathode electrode CE3. The fabricating process will be described later.

In the portion overlapping the non-light emitting area NLA, the first to third inorganic layers 171-1, 171-2, and 171-3 may be disposed such that the first to third inorganic layers 171-1, 171-2, and 171-3 are spaced apart from each other in the first direction (X-axis direction), and the second encapsulation layer 173 may be disposed between the first to third inorganic layers 171-1, 171-2, and 171-3 spaced apart from each other. The first to third inorganic layers 171-1, 171-2, and 171-3 according to an embodiment may be formed to entirely cover the third bank layer 165 during the process of fabricating the display device 10, and portions of the first to third inorganic layers 171-1, 171-2, and 171-3 may be then removed through a subsequent etching process. Therefore, the first to third inorganic layers 171-1, 171-2, and 171-3 may include a trench portion TP in the portion overlapping the non-light emitting area NLA.

The second encapsulation layer 173 according to an embodiment may be disposed on the first encapsulation layer 171 and may planarize a step formed by the first encapsulation layer 171. The second encapsulation layer 173 may include a polymer-based material. As an example, the second encapsulation layer 173 may include one or more of an acrylic resin, an epoxy resin, a silicone resin, a silicone acrylic resin, polyimide, and polyethylene.

The third encapsulation layer 175 according to an embodiment may be disposed on the second encapsulation layer 173 and entirely cover the second encapsulation layer 173. Since the third encapsulation layer 175 may be formed through a chemical vapor deposition (CVD) process, the third encapsulation layer 175 may be formed to have a uniform thickness. The third encapsulation layer 175 may include the same material as the first encapsulation layer 171.

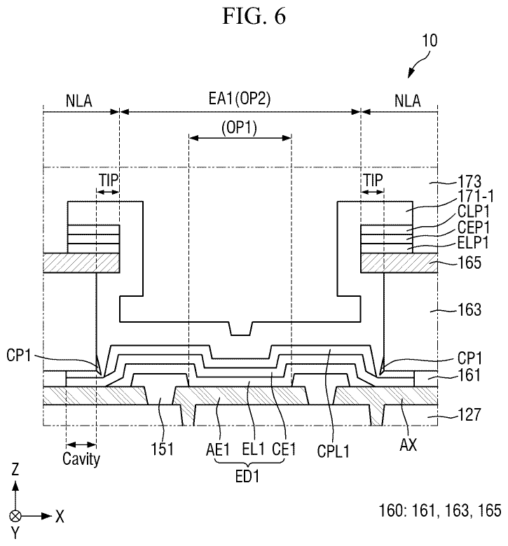

FIG. 6 is an enlarged schematic cross-sectional view of a first light emitting area EA1 of FIG. 5.

Referring to FIG. 6, the first anode electrode AE1 according to an embodiment may be positioned such that the first anode electrode AE1 is spaced apart from a plurality of auxiliary electrodes AX in the first direction (X-axis direction) on the second via layer 127, and the first anode electrode AE1 may be disposed between the plurality of auxiliary electrodes AX. The pixel defining layer 151 may be positioned between the first anode electrode AE1 and the auxiliary electrode AX spaced apart from each other.

In a portion overlapping the first opening OP1, the first light emitting layer EL1 according to an embodiment may be disposed on the first anode electrode AE1 and may completely cover the first anode electrode AE1. In some aspects, in a portion overlapping the second opening OP2, the first light emitting layer EL1 according to an embodiment may be disposed on the pixel defining layer 151 and the auxiliary electrode AX, may completely cover the pixel defining layer 151, and may cover a portion of the auxiliary electrode AX. In a portion overlapping the non-light emitting area NLA, the first light emitting layer EL1 according to an embodiment may be in contact with a portion of the auxiliary electrode AX and may not overlap the cavity disposed between the first bank layer 161 and the second bank layer 163. In some aspects, the first light emitting layer EL1 according to an embodiment may not be in contact with the bank structure 160.

The first cathode electrode CE1 according to an embodiment may completely cover the first light emitting layer EL1 in a portion overlapping the second opening OP2. Furthermore, in a portion overlapping the non-light emitting area NLA, the first cathode electrode CE1 according to an embodiment may cover the auxiliary electrode AX and may be in contact with the auxiliary electrode AX. In other words, in a portion overlapping the cavity, the first cathode electrode CE1 according to an embodiment may cover the auxiliary electrode AX and may be in contact with the auxiliary electrode AX. The first cathode electrode CE1 according to an embodiment may be electrically connected to the auxiliary electrode AX.

As described herein, the deposition process of forming the first cathode electrode CE1 according to an embodiment may have a higher step coverage than the deposition process of forming the first light emitting layer EL1. Therefore, as a portion of the material forming the first cathode electrode CE1 according to an embodiment is in contact with the bank structure 160 according to an embodiment during the process of fabricating the display device 10, the first residual electrode pattern CP1 may be formed.

The first capping layer CPL1 according to an embodiment may completely cover the first cathode electrode CE1 in a portion overlapping the first opening OP1, and may cover a portion of the first cathode electrode CE1 in a portion overlapping the second opening OP2. This may be achieved because the deposition process of forming the first cathode electrode CE1 during the process of fabricating the display device 10 is a process with a higher step coverage than the deposition process of forming the first capping layer CPL1. Redundant descriptions will be omitted. The first capping layer CPL1 according to an embodiment may not overlap the cavity disposed between the first bank layer 161 and the second bank layer 163, and the first capping layer CPL1 may not be in contact with the bank structure 160.

The first bank layer 161 according to an embodiment may be positioned on the auxiliary electrode AX. The first bank layer 161 may be disposed to be in contact with the auxiliary electrode AX in a portion overlapping the non-light emitting area NLA. The first bank layer 161 according to an embodiment may include an inorganic insulating material or metal. As an example, the first bank layer 161 may be silicon nitride or aluminum, but is not limited thereto.

The cavity may be formed between the first bank layer 161 and the second bank layer 163 according to an embodiment. Details will be described later.

The second bank layer 163 according to an embodiment may be positioned on the first bank layer 161. The second bank layer 163 may be disposed to be in contact with the first bank layer 161 in a portion overlapping the non-light emitting area NLA. The second bank layer 163 according to an embodiment may include an inorganic insulating material. As the second bank layer 163 includes an inorganic insulating material, interfacial adhesion with the first inorganic layer 171-1 may be improved. Therefore, the display device 10 according to an embodiment may solve external moisture permeation defects caused by defective detachment of the second bank layer 163 and the first inorganic layer 171-1.

The first bank layer 161 and the second bank layer 163 according to an embodiment may include different insulating materials. As the first bank layer 161 and the second bank layer 163 include different materials, the first bank layer 161 and the second bank layer 163 may have different etching rates even if the same etching process is performed in the process of fabricating the display device 10. That is, the first bank layer 161 and the second bank layer 163 may be formed as different shapes even if the same etching process is performed. As an example, the second bank layer 163 may include silicon oxide, but is not limited thereto. For example, the second bank layer 163 may be silicon oxide, but is not limited thereto.

The third bank layer 165 according to an embodiment may be positioned on the second bank layer 163. The third bank layer 165 may be disposed to be in contact with the second bank layer 163 in a portion overlapping the non-light emitting area NLA. The third bank layer 165 according to an embodiment may include a metal that is stable in an etching process. As an example, the third bank layer 165 may include titanium (Ti).

The third bank layer 165 according to an embodiment may be more stable in the etching process than the first bank layer 161 and the second bank layer 163 during the process of fabricating the display device 10, and as a result, the third bank layer 165 according to an embodiment may include a tip that protrudes further toward the first light emitting area EA1 than the second bank layer 163.

In the display device 10 according to an embodiment, as the third bank layer 165 includes the tip, the first light emitting element ED1 disposed to overlap the first light emitting area EA1 may be formed without a fin metal mask during the process of fabricating the display device 10. The fabricating process will be described later.

The first organic pattern ELP1 according to an embodiment may be disposed on the third bank layer 165 and may be in contact with the tip of the third bank layer 165. In some aspects, the first electrode pattern CEP1 and the first capping pattern CLP1 according to an embodiment may overlap the tip of the third bank layer 165 in the third direction (Z-axis direction). Other redundant descriptions will be omitted.

The first inorganic layer 171-1 according to an embodiment may completely cover the first light emitting element ED1 and the first capping layer CPL1 in a portion overlapping the first opening OP1, and may cover the first cathode electrode CE1, the first capping layer CPL1, the first residual electrode pattern CP1, and the first capping pattern CLP1 in a portion overlapping the second opening OP2 and the non-light emitting area NLA.

The first inorganic layer 171-1 according to an embodiment may perform the covering along a profile formed by the first bank layer 161, the second bank layer 163, and the third bank layer 165. Specifically, the first inorganic layer 171-1 according to an embodiment may be disposed in a portion overlapping the cavity and may cover the first cathode electrode CE1 in the portion overlapping the cavity. For convenience of explanation, it is illustrated in the drawing that the first cathode electrode CE1 and the first inorganic layer 171-1 are in contact with the first bank layer 161, but embodiments of the present disclosure are not limited thereto. Depending on process conditions, the first cathode electrode CE1 and the first inorganic layer 171-1 may also be in non-contact with the first bank layer 161.

The first inorganic layer 171-1 according to an embodiment may cover the second bank layer 163 and the first residual electrode pattern CP1, and may be in contact with the second bank layer 163 and the first residual electrode pattern CP1 Furthermore, the first inorganic layer 171-1 according to an embodiment may cover the protruding tip of the third bank layer 165 and may be in contact with the protruding tip of the third bank layer 165. In some aspects, the first inorganic layer 171-1 according to an embodiment may cover portions of the first organic pattern ELP1, the first electrode pattern CEP1, and the first capping pattern CLP1, and the first inorganic layer 171-1 may be in contact with the portions of the first organic pattern ELP1, the first electrode pattern CEP1, and the first capping pattern CLP1. Other redundant descriptions will be omitted.

The second encapsulation layer 173 according to an embodiment may planarize a step formed by the first inorganic layer 171-1 in portions overlapping the first light emitting area EA1 and the non-light emitting area NLA. The second encapsulation layer 173 according to an embodiment may be in contact with the third bank layer in the portion overlapping the non-light emitting area NLA. Details will be described later.

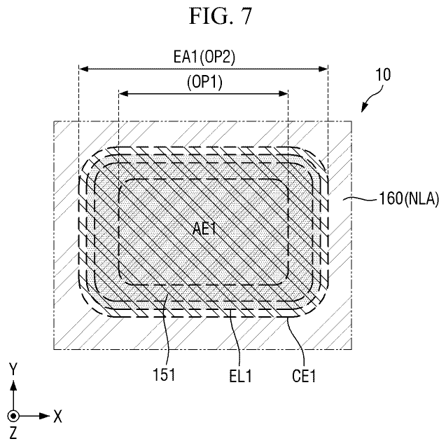

FIG. 7 is a schematic plan view illustrating the first light emitting area EA1 of FIG. 6.

Referring to FIG. 7, in the plan view, the pixel defining layer 151 may define the first opening OP1, and may expose the first anode electrode AE1 in a portion overlapping the first opening OP1. In the plan view, the pixel defining layer 151 may completely surround the first anode electrode AE1. In the plan view, the pixel defining layer 151 according to an embodiment may be positioned inside the first light emitting area EA1.

In the plan view, the first light emitting layer EL1 may completely cover the first anode electrode AE1 and the pixel defining layer 151. In some aspects, in the plan view, the first cathode electrode CE1 may completely cover the first light emitting layer EL1, the first anode electrode AE1, and the pixel defining layer 151. In other words, in the plan view, the first anode electrode AE1 and the pixel defining layer 151 may be disposed inside the first light emitting layer EL1, and in the plan view, the first anode electrode AE1, the pixel defining layer 151, and the first light emitting layer EL1 may be disposed inside the first cathode electrode CE1.

In the plan view, the non-light emitting area NLA may be defined by a portion overlapping the bank structure 160. In some aspects, in the plan view, the bank structure 160 may define the second opening OP2, expose the first cathode electrode CE1 in a portion overlapping the second opening OP2, and completely surround the first cathode electrode CE1.

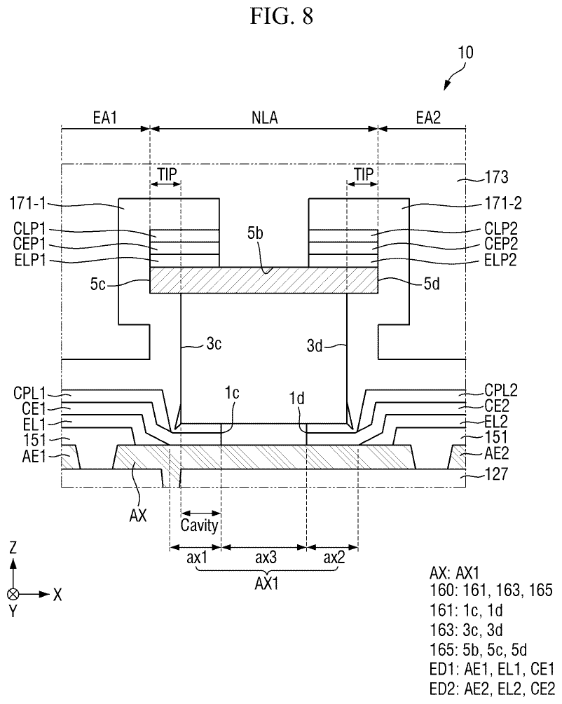

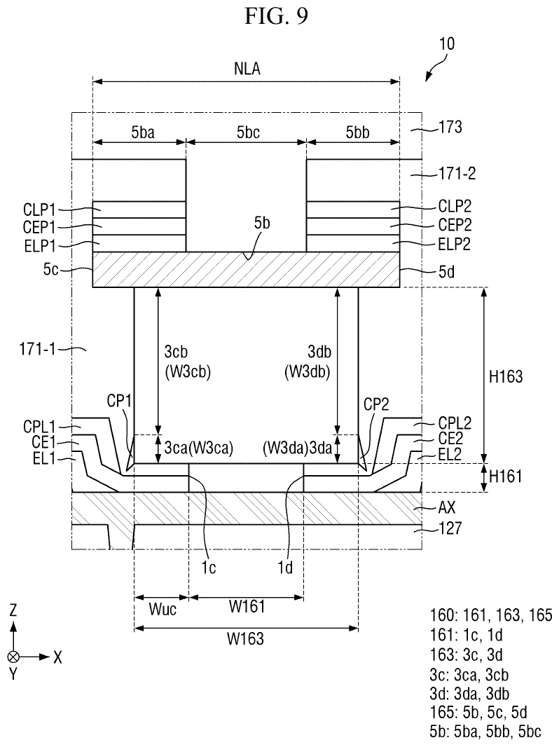

FIG. 8 is an enlarged schematic cross-sectional view of a non-light emitting area NLA disposed between a first light emitting area EA1 and a second light emitting area EA2 of FIG. 5. FIG. 9 is an enlarged cross-sectional view of a bank structure 160 of FIG. 8.

Referring to FIG. 8, the first light emitting area EA1 and the second light emitting area EA2 according to an embodiment may be spaced apart from each other with the non-light emitting area NLA interposed between the first light emitting area EA1 and the second light emitting area EA2.

The auxiliary electrode AX according to an embodiment may be disposed on the second via layer 127 and may be disposed between the first anode electrode AE1 and the second anode electrode AE2. The auxiliary electrode AX may be disposed in a portion overlapping the non-light emitting area NLA, and the auxiliary electrode AX may be spaced apart from the first anode electrode AE1 and the second anode electrode AE2 with the pixel defining layer 151 interposed between the auxiliary electrode AX and the first anode electrode AE1 and the second anode electrode AE2.

In some embodiments, the auxiliary electrode AX according to an embodiment may include a first surface AX1 facing the bank structure 160. The first surface AX1 may have a first portion ax1, a second portion ax2, and a third portion ax3 depending on a structure in contact therewith. Specifically, the first portion ax1 may be a portion in contact with the first cathode electrode CE1, the second portion ax2 may be a portion in contact with the second cathode electrode CE2, and the third portion ax3 may be a portion in contact with the first bank layer 161. The third portion ax3 may be positioned between the first portion ax1 and the second portion ax2.

As the auxiliary electrode AX according to an embodiment includes the first portion ax1 and the second portion ax2, the auxiliary electrode AX may electrically connect the first cathode electrode CE1 and the second cathode electrode CE2 which are spaced apart from each other in the first light emitting area EA1 and the second light emitting area EA2, respectively.

The first bank layer 161 according to an embodiment may space the auxiliary electrode AX and the second bank layer 163 from each other in the third direction (Z-axis direction), and may space the first cathode electrode CE1 and the second cathode electrode CE2 from each other in the first direction (X-axis direction).

In some embodiments, the first bank layer 161 may include a first side surface 1c and a second side surface 1d. The first side surface 1c may be disposed toward the first light emitting area EA1, and the second side surface 1d may be disposed toward the second light emitting area EA2.

The first side surface 1c according to an embodiment may be more depressed toward one side in the first direction (X-axis direction) than a first side surface 3c of the second bank layer 163. Therefore, an undercut may be formed between the second bank layer 163 and the first side surface 1c of the first bank layer 161, and a cavity may be formed in a portion in which the undercut is formed. The second side surface 1d according to an embodiment may be more depressed toward the other side in the first direction (X-axis direction) than a second side surface 3d of the second bank layer 163. Therefore, an undercut may be formed between the second bank layer 163 and the second side surface 1d of the first bank layer 161, and a cavity may be formed in a portion in which the undercut is formed.

As the display device 10 according to an embodiment includes the cavity formed between the first bank layer 161 and the second bank layer 163, the formed cavity may assist in ensuring that the first cathode electrode CE1 and the second cathode electrode CE2 are disposed in the cavity, without the first and second light emitting layers EL1 and EL2 being formed in a portion overlapping the cavity. This may be achieved by step coverage characteristics of each performed process. Redundant descriptions will be omitted.

The second bank layer 163 according to an embodiment may be disposed on the first bank layer 161, and may space the first light emitting element ED1 and the second light emitting element ED2 from each other. In some aspects, the second bank layer 163 may be in contact with the first inorganic layer 171-1 and the second inorganic layer 171-2, and may space the first inorganic layer 171-1 and the second inorganic layer 171-2 from each other.

In some embodiments, the second bank layer 163 according to an embodiment may include a first side surface 3c and a second side surface 3d. The first side surface 3c may be disposed toward the first light emitting area EA1, and the second side surface 3d may be disposed toward the second light emitting area EA2. The first side surface 3c of the second bank layer 163 may protrude further toward the first light emitting area EA1 than the first side surface 1c of the first bank layer 161, and may be depressed more toward one side in the first direction (X-axis direction) than a first side surface 5c of the third bank layer 165. Therefore, an undercut may be formed between the first side surface 3c of the second bank layer 163 and the third bank layer 165.

In some aspects, the second side surface 3d of the second bank layer 163 may protrude further toward the second light emitting area EA2 than the second side surface 1d of the first bank layer 161, and may be depressed more toward the other side in the first direction (X-axis direction) than a second side surface 5d of the third bank layer 165. Therefore, an undercut may be formed between the second side surface 3d of the second bank layer 163 and the third bank layer 165.

Referring to FIG. 9, the first side surface 3c of the second bank layer 163 may include a first portion 3ca in contact with the first residual electrode pattern CP1 and a second portion 3cb in contact with the first inorganic layer 171-1. An area W3ca of the first portion 3ca may be smaller than an area W3cb of the second portion 3cb. In the display device 10 according to an embodiment, as the area W3cb of the second portion 3cb is formed to be greater than the area W3ca of the first portion 3ca, the adhesion between the second bank layer 163 and the first inorganic layer 171-1 may be increased, thereby solving external air moisture permeation defects caused by defective detachment of the display device 10.

In some embodiments, the second side surface 3d of the second bank layer 163 may include a first portion 3da in contact with the second residual electrode pattern CP2 and a second portion 3db in contact with the second inorganic layer 171-2. An area W3da of the first portion 3da may be smaller than an area W3db of the second portion 3db. Redundant descriptions will be omitted.

In some embodiments, a height H161 of the first bank layer 161 according to an embodiment may be smaller than a height H163 of the second bank layer 163, and a width W161 of the first bank layer 161 according to an embodiment may be smaller than a width W163 of the second bank layer 163. As an example, the height H161 of the first bank layer 161 according to an embodiment may range from 500 angstroms to 2000 angstroms, and the height H163 of the second bank layer 163 may range from 5,000 angstroms to 10,000 angstroms.

The width W163 of the second bank layer 163 according to an embodiment may be equal to a width Wuc of the undercut formed between both side surfaces of the first bank layer 161 according to an embodiment and the second bank layer 163 plus the width W161 of the first bank layer 161. As an example, the width Wuc of the undercut according to an embodiment may be more than twice the height H161 of the first bank layer 161. As an example, a width of the cavity corresponding to the undercut may be more than twice the height H161 of the first bank layer 161. In some aspects, the width of the cavity in a direction parallel to the substrate 110 may be more than twice the height H161 of the first bank layer 161.

Referring to FIG. 8, the third bank layer 165 according to an embodiment may include a first side surface 5c, a second side surface 5d, and a first surface 5b. The first side surface 5c may be disposed toward the first light emitting area EA1, the second side surface 5d may be disposed toward the second light emitting area EA2, and the first surface 5b may be disposed toward the second encapsulation layer 173.

The first side surface 5c according to an embodiment may protrude further toward the first light emitting area EA1 than the first side surface 3c of the second bank layer 163, and as a result, the third bank layer 165 may have a tip that protrudes further toward the first light emitting area EA1 than the first side surface 3c of the second bank layer 163. In some aspects, the second side surface 5d according to an embodiment may protrude further toward the second light emitting area EA2 than the second side surface 3d of the second bank layer 163, and as a result, the third bank layer 165 may have a tip that protrudes further toward the second light emitting area EA2 than the second side surface 3d of the second bank layer 163. That is, the third bank layer 165 may have the tips that protrude on both sides toward the first and second light emitting areas EA1 and EA2.

Referring to FIG. 9, the first surface 5b of the third bank layer 165 may be divided into a first portion 5ba, a second portion 5bb, and a third portion 5bc depending on a contact structure. The first portion 5ba and the second portion 5bb according to an embodiment may be spaced apart from each other with the third portion 5bc interposed between the first portion 5ba and the second portion 5bb.

The first portion 5ba according to an embodiment may be in contact with the first organic pattern ELP1, and may overlap the first electrode pattern CEP1, the first capping pattern CLP1, and the first inorganic layer 171-1 in the third direction (Z-axis direction). The second portion 5bb according to an embodiment may be in contact with the second organic pattern ELP2, and may overlap the second electrode pattern CEP2, the second capping pattern CLP2, and the second inorganic layer 171-2 in the third direction (Z-axis direction). The third portion 5bc according to an embodiment may be positioned between the first portion 5ba and the second portion 5bb and may be in contact with the second encapsulation layer 173. The third portion 5bc according to an embodiment may not overlap the first organic pattern ELP1, the first electrode pattern CEP1, the first capping pattern CLP1, the first inorganic layer 171-1, the second organic pattern ELP2, the second electrode pattern CEP2, the second capping pattern CLP2, and the second inorganic layer 171-2 in the third direction (Z-axis direction).

For convenience of explanation, the structure overlapping the first light emitting area EA1 and the second light emitting area EA2 is illustrated and then described, but the third light emitting area EA3 may have the same structure and characteristics as the first light emitting area EA1 and the second light emitting area EA2.

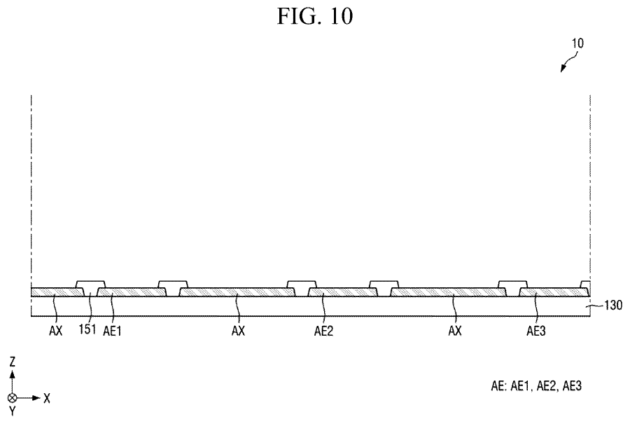

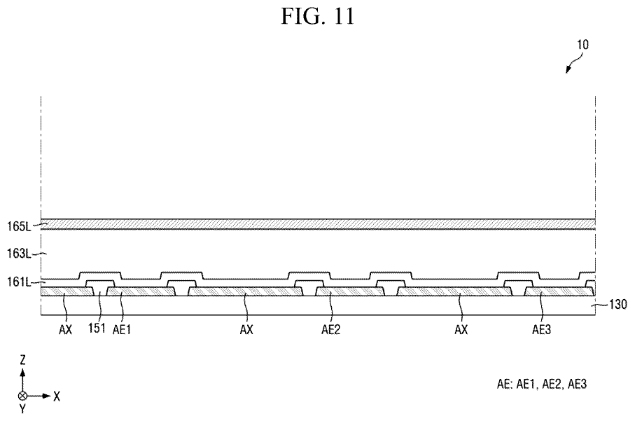

FIGS. 10 to 21 are cross-sectional views schematically illustrating a method of fabricating a display element layer 150 and a thin film encapsulation layer 170 included in the display device 10 of FIG. 5.

In the descriptions of the method and processes herein, the operations may be performed in a different order than the order shown and/or described, or the operations may be performed in different orders or at different times. Certain operations may also be left out of the method and processes, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 10, the method may include forming a plurality of anode electrodes AE and a plurality of auxiliary electrodes AX on a thin film transistor layer 130, in which the plurality of anode electrodes AE are spaced apart from each other and the plurality of auxiliary electrodes AX are spaced apart from each other, and the method may include forming a pixel defining layer 151 between the plurality of anode electrodes AE and the plurality of auxiliary electrodes AX. The anode electrode AE may include first to third anode electrodes AE1, AE2, and AE3.

The auxiliary electrode AX according to an embodiment may include the same material as the anode electrode AE, or may include a different material from the anode electrode AE. In an example according to an embodiment in which the method includes forming the auxiliary electrode AX of the same material as the anode electrode AE, the method may have an advantage of process simplification with respect to forming the auxiliary electrode AX. Although not illustrated, the thin film transistor layer 130 may be disposed on the substrate 110, and a structure of the thin film transistor layer 130 is the same as that described herein with reference to FIG. 5. A detailed description thereof will be omitted.

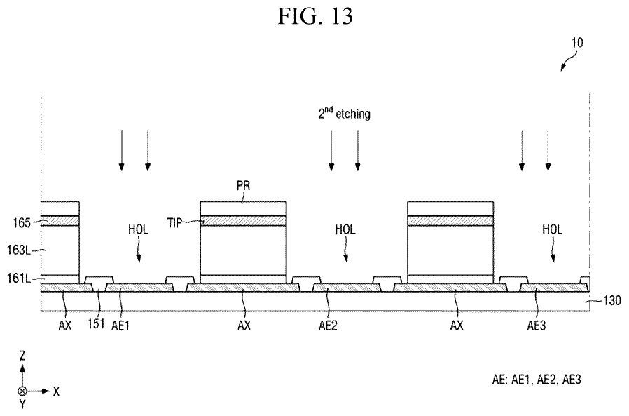

Next, referring to FIG. 13, the method may include forming a first bank material layer 161L, a second bank material layer 163L, and a third bank material layer 165L, such that the first bank material layer 161L, the second bank material layer 163L, and the third bank material layer 165L are entirely formed on the plurality of anode electrodes AE, the plurality of auxiliary electrodes AX, and the pixel defining layer 151. The method may include sequentially stacking and disposing the first bank material layer 161L, the second bank material layer 163L, and the third bank material layer 165L.

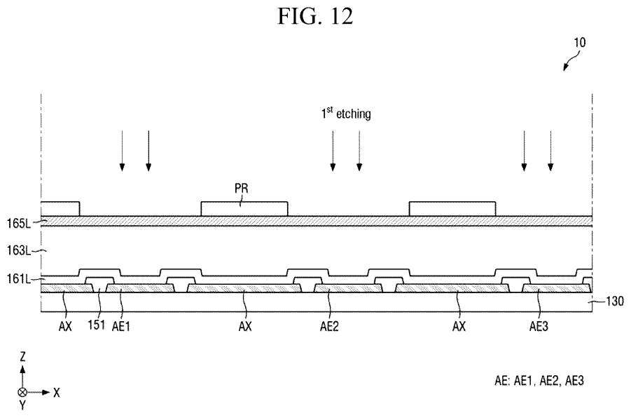

Next, referring to FIGS. 12 and 13, the method may include forming a photoresist PR except for portions that overlap the anode electrode AE and the pixel defining layer 151. For example, the method may include forming the photoresist PR such that the photoresist PR does not overlap the anode electrode AE and the pixel defining layer 151. Next, the method may include performing a first etching process of etching portions of the first bank material layer 161L, the second bank material layer 163L, and the third bank material layer 165L using the photoresist PR as a mask. In an embodiment, the first etching process may include isotropic dry etching. The portions of the first bank material layer 161L, the second bank material layer 163L, and the third bank material layer 165L at the portions where the photoresist PR is not formed may be isotropically etched through the first etching process. The terms “portions” may refer to “regions” or “areas” associated with performing the method (e.g., forming, etching, and the like).

As illustrated in FIG. 13, in the present process, the method may include removing portions of the first bank material layer 161L, the second bank material layer 163L, and the third bank material layer 165L of portions overlapping the plurality of anode electrodes AE, and as a result, a hole HOL may be formed in the portions overlapping the plurality of anode electrodes AE, and the plurality of anode electrodes AE and the pixel defining layer 151 may be exposed. Through the present process, the third bank material layer 165L may be formed in the form of the third bank layer 165 illustrated in FIG. 5.

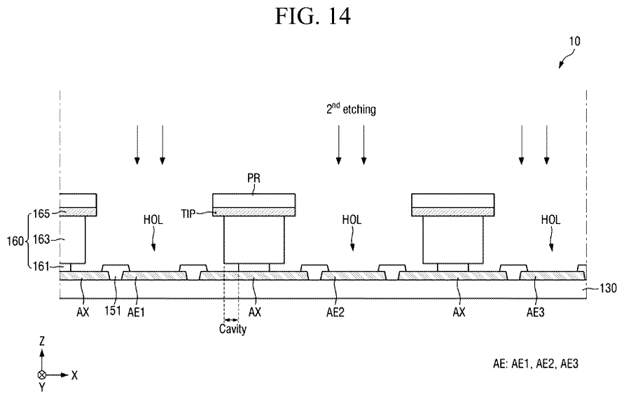

Next, referring to FIGS. 13 and 14, after a photoresist PR covering the same portion as the first etching process is formed on the third bank layer 165, the method may include performing a second etching process using the photoresist PR as a mask. In an embodiment, the second etching process may include anisotropic dry etching. In the present process, the second etching process may remove portions of the inside of the first bank material layer 161L and the second bank material layer 163L in the portion overlapping the hole HOL.

The first bank material layer 161L and the second bank material layer 163L according to an embodiment may include different materials. For example, a material included the first bank material layer 161L may differ from a material included in the second bank material layer 163L. Therefore, the first bank material layer 161L and the second bank material layer 163L may have different etching rates. That is, in the display device 10 according to an embodiment, the method may include adjusting materials and process conditions such that the etching rate of the first bank material layer 161L is greater than the etching rate of the second bank material layer 163L in the same etching process. As an example, when the first bank material layer 161L is formed of silicon nitride, the second bank material layer 163L may be formed of silicon oxide. However, this is only an example, and the disclosure is not limited thereto.

In the present process, the first bank material layer 161L may be formed in the form of the first bank layer 161 illustrated in FIG. 5, and the second bank material layer 163L may be formed in the form of the second bank layer 163 illustrated in FIG. 5. In other words, the second bank layer 163 may have a structure that protrudes further on both sides toward the hole HOL than the first bank layer 161, and the third bank layer 165 may have a structure that protrudes further on both sides toward the hole HOL than the second bank layer 163. As a result, the third bank layer 165 may have a tip that protrudes further toward the hole HOL than the second bank layer 163, and a cavity may be formed between the first bank layer 161 and the second bank layer 163.

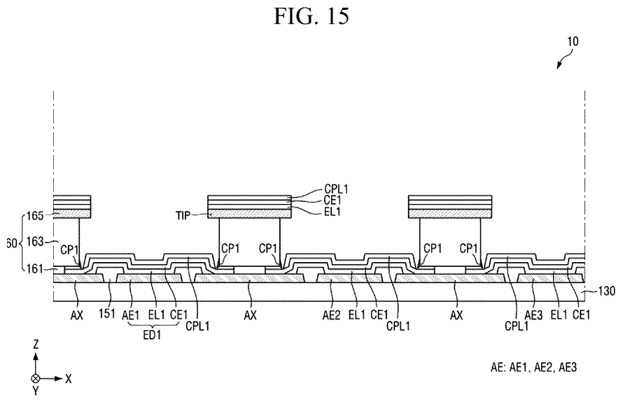

Next, referring to FIG. 15, the method may include forming a first light emitting element ED1 by depositing a first light emitting layer EL1 and the first cathode electrode CE1 on the first anode electrode AE1, and the method may include then depositing a first capping layer CPL1. In the display device 10 according to an embodiment, as the third bank layer 165 includes the tip, the first light emitting layer EL1, the first cathode electrode CE1, and the first capping layer CPL1 may be formed on the first anode electrode AE1 through a deposition and photo patterning process without a separate fine metal mask.

The method may include forming the first light emitting layer EL1 according to an embodiment through a thermal deposition process. The deposition process of forming the first light emitting layer EL1 according to an embodiment may be performed at an angle of 45° to 50° from an upper surface of the first anode electrode AE1. As a result, the first light emitting layer EL1 may be formed on the pixel defining layer 151 and the auxiliary electrode AX that are hidden (e.g., according to the plan view) under the tip of the third bank layer 165. However, the first light emitting layer EL1 according to an embodiment may not be deposited on a portion overlapping the cavity formed between the first bank layer 161 and the second bank layer 163.

The method may include forming the first cathode electrode CE1 according to an embodiment through a thermal deposition process or a sputtering deposition process. In an example in which the first cathode electrode CE1 according to an embodiment is formed through a thermal deposition process, the deposition process of forming the first cathode electrode CE1 may be performed at an angle of 30° or less from the upper surface of the first anode electrode AE1. In other words, compared to the deposition process of forming the first light emitting layer EL1, the deposition process of forming the first cathode electrode CE1 may be performed such that the formation of the first cathode electrode CE1 is inclined in a relatively more horizontal direction. That is, the deposition process of forming the first cathode electrode CE1 may have a higher step coverage than the deposition process of forming the first light emitting layer EL1. As a result, the first cathode electrode CE1 may completely cover the first light emitting layer EL1. In some aspects, the method may include forming the first cathode electrode CE1 according to an embodiment through a sputtering deposition process, and the sputtering deposition process of forming the first cathode electrode CE1 may have higher step coverage characteristics than the thermal deposition process.

The method may include depositing the first cathode electrode CE1 according to an embodiment on a portion overlapping the cavity formed between the first bank layer 161 and the second bank layer 163 in addition to an upper surface of the first light emitting layer EL1. The first cathode electrode CE1 according to an embodiment may be in contact with the auxiliary electrode AX at a portion overlapping the cavity.

The method may include partially depositing the material forming the first cathode electrode CE1 according to an embodiment on the side surface of the second bank layer 163, which may be the first residual metal pattern CP1 illustrated in FIG. 5. The first residual metal pattern CP1 may be formed such that the first residual metal pattern CP1 is spaced apart from the first cathode electrode CE1.

The method may include forming the first capping layer CPL1 according to an embodiment through a thermal deposition process, and the first capping layer CPL1 may have lower step coverage characteristics than the first cathode electrode CE1. Therefore, the first capping layer CPL1 according to an embodiment may not be deposited on a portion overlapping the cavity formed between the first bank layer 161 and the second bank layer 163.

In some aspects, the first light emitting layer EL1, the first cathode electrode CE1, and the first capping layer CPL1 according to an embodiment may be deposited on the first anode electrode AE1 and also on the third bank layer 165, the second anode electrode AE2, and the third anode electrode AE3. As the third bank layer 165 includes the tip, the first light emitting layer EL1, the first cathode electrode CE1, and the first capping layer CPL1 deposited on the third bank layer 165 may be spaced apart from the first light emitting layer EL1, the first cathode electrode CE1, and the first capping layer CPL1 deposited on the first anode electrode AE1, the second anode electrode AE2, and the third anode electrode AE3.

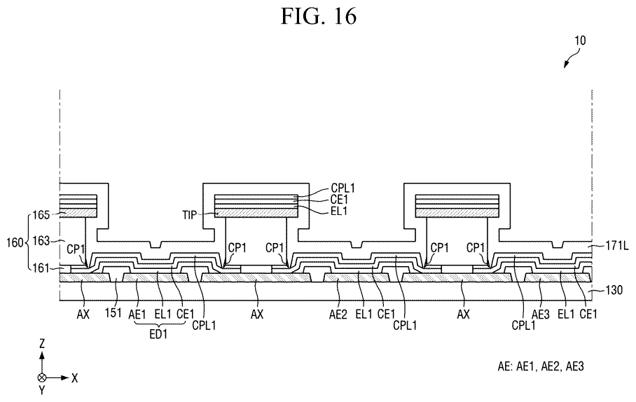

Next, referring to FIG. 16, the method may include forming a first encapsulation material layer 171L such that the first encapsulation material layer 171L is entirely formed on the first capping layer CPL1 and the first cathode electrode CE1. The method may include forming the first encapsulation material layer 171L by a chemical vapor deposition (CVD) process, and the first encapsulation material layer 171L may form a uniform film regardless of a step of a lower structure. As an example, the first encapsulation material layer 171L may cover the step formed by the first light emitting element ED1, may cover the undercut portion formed between the second bank layer 163 and the tip of the third bank layer 165, and may be deposited such that the first encapsulation material layer 171L overlaps within the cavity formed between the first bank layer 161 and the second bank layer 163. In some aspects, the first encapsulation material layer 171L may entirely cover the first capping layer CPL1 disposed on the third bank layer 165.

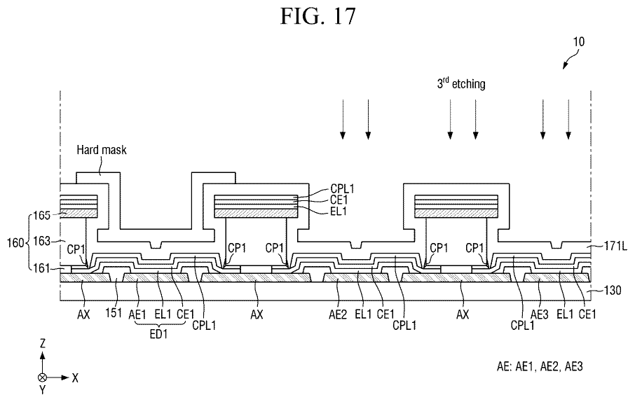

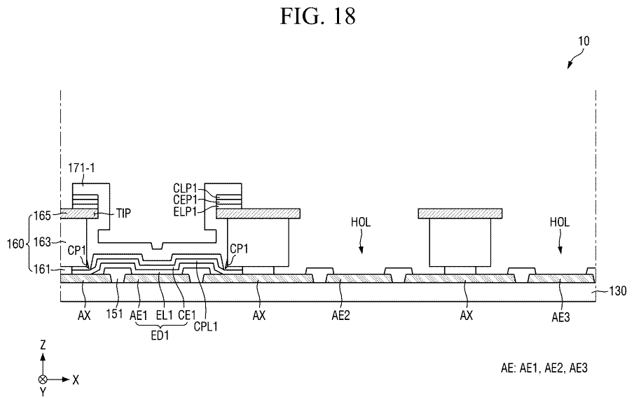

Next, referring to FIGS. 17 and 18, after a hard mask is formed on the first light emitting element ED1 and an overlapping portion around the first light emitting element ED1, the method may include performing a third etching process of removing a portion where the hard mask is not formed. In the present process, the third etching process may remove all the first light emitting layer EL1, the first cathode electrode CE1, the first capping layer CPL1, and the first encapsulation material layer 171L in the portion where the hard mask is not formed. The hard mask used in the present process may be indium gallium zinc oxide (IGZO).

In the present process, the method may include forming the first encapsulation material layer 171L in the form of the first inorganic layer 171-1 illustrated in FIG. 5, and the method may include forming the first light emitting layer EL1, the first cathode electrode CE1, and the first capping layer CPL1, which were deposited on the third bank layer 165, in the form of the first organic pattern ELP1, the first electrode pattern CEP1, and the first capping pattern CLP1 illustrated in FIG. 5.

In the present process, the method may include again exposing the second anode electrode AE2 and the pixel defining layer 151 disposed around the second anode electrode AE2, and a hole HOL may be formed in a portion overlapping the second anode electrode AE2. In some aspects, the method may include again exposing the third anode electrode AE3 and the pixel defining layer 151 disposed around the third anode electrode AE3, and a hole HOL may be formed in a portion overlapping the third anode electrode AE3.

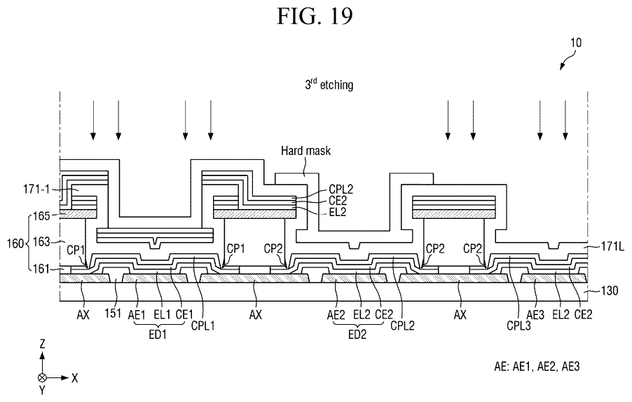

Next, referring to FIG. 19, the method may include forming a second light emitting element ED2 by repeating the above-described processes. Specifically, the method may include depositing the second light emitting layer EL2, the second cathode electrode CE2, the second capping layer CPL2, and the first encapsulation material layer 171L such that the second light emitting layer EL2, the second cathode electrode CE2, the second capping layer CPL2, and the first encapsulation material layer 171L are entirely deposited on the second anode electrode AE2. In the present process, the method may include forming the second light emitting layer EL2, the second cathode electrode CE2, the second capping layer CPL2, and the first encapsulation material layer 171L on the second anode electrode AE2 and also on the first inorganic layer 171-1, the third anode electrode AE3, and the third bank layer 165 overlapping the first anode electrode AE1. Other redundant descriptions will be omitted.

Next, the method may include forming a hard mask on the second light emitting element ED2 and an overlapping portion around the second light emitting element ED2, and the method may include partially etching a portion where the hard mask is not formed. The etching process of the present process may be the same as the third etching process.

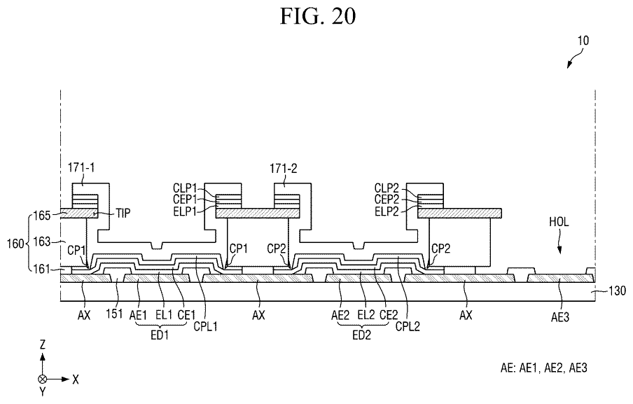

Referring to FIG. 20, in the present process, the method may include forming the first encapsulation material layer 171L in the form of the second inorganic layer 171-2 illustrated in FIG. 5. The first inorganic layer 171-1 and the second inorganic layer 171-2 may be spaced apart from each other in the first direction (X-axis direction) on the third bank layer 165. In some aspects, the method may include forming the second light emitting layer EL2, the second cathode electrode CE2, and the second capping layer CPL2, which were deposited on the third bank layer 165, in the form of the second organic pattern ELP2, the second electrode pattern CEP2, and the second capping pattern CLP2 illustrated in FIG. 5. The second organic pattern ELP2, the second electrode pattern CEP2, and the second capping pattern CLP2 may be spaced apart from the first organic pattern ELP1, the first electrode pattern CEP1, and the first capping pattern CLP1 in the first direction (X-axis direction) on the third bank layer 165.

In the present process, the method may include exposing the third anode electrode AE3 and the pixel defining layer 151 of a portion overlapping the third anode electrode AE3, and a hole HOL may be formed in a portion overlapping the third anode electrode AE3. Next, the method may include forming a third light emitting element ED3 by repeating the above-described processes. An overlapping description will be omitted.

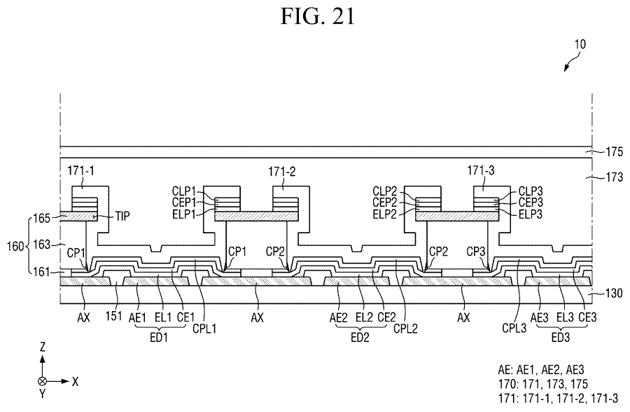

Referring to FIG. 21, through the above-described process, the first encapsulation material layer 171L may be formed in the form of the third inorganic layer 171-3 illustrated in FIG. 5, and the second inorganic layer 171-2 and the third inorganic layer 171-3 may be spaced apart from each other in the first direction (X-axis direction) on the third bank layer 165.

In the present process, the method may include forming the third light emitting layer EL3, the third cathode electrode CE3, and the third capping layer CPL3, which were deposited on the third bank layer 165, in the form of the third organic pattern ELP3, the third electrode pattern CEP3, and the third capping pattern CLP3 illustrated in FIG. 5. The third organic pattern ELP3, the third electrode pattern CEP3, and the third capping pattern CLP3 may be spaced apart from the second organic pattern ELP2, the second electrode pattern CEP2, and the second capping pattern CLP2 in the first direction (X-axis direction) on the third bank layer 165.

Next, the method may include forming a second encapsulation layer 173 to planarize the step included in the first encapsulation layer 171, and then forming a third encapsulation layer 175. As a result, the display element layer 150 and the thin film encapsulation layer 170 illustrated in FIG. 5 may be formed.

In the display device 10 according to an embodiment, as the third bank layer 165 includes the tip, the first to third light emitting elements ED1, ED2, and ED3 spaced apart from each other may be formed without a separate fin metal mask, and as the first to third cathode electrodes CE1, CE2, and CE3 overlap the cavity formed between the first bank layer 161 and the second bank layer 163 and is in contact with the auxiliary electrode AX, the first to third cathode electrodes CE1, CE2, and CE3 spaced apart from each other may be electrically connected. In some aspects, in the display device 10 according to an embodiment, as high adhesion between the second bank layer 163 and the first encapsulation layer 171 is formed, the defective detachment of the second bank layer 163 and the first encapsulation layer 171 may be solved, and moisture permeation defects due to external air caused by the defective detachment may be solved.

The example aspects supported by the present disclosure should not be construed as being limited to the embodiments set forth herein. Rather, the example embodiments are provided such that this disclosure will be thorough and complete and will fully convey the concept of the invention to those skilled in the art.

While the example aspects supported by the present disclosure have been particularly illustrated and described with reference to embodiments thereof, it will be understood by those of ordinary skill in the art that various changes in form and details may be made therein without departing from the spirit or scope of the example embodiments of the present disclosure as defined by the following claims.

What is claimed is:

1. A display device comprising:
a substrate comprising a light emitting area and a non-light emitting area;
a first anode electrode positioned on the light emitting area of the substrate;
an auxiliary electrode positioned on the non-light emitting area of the substrate and spaced apart from the first anode electrode;
a pixel defining layer positioned on the first anode electrode and the auxiliary electrode and defining a first opening;
a first light emitting layer positioned on the first anode electrode and completely covering the pixel defining layer;
a first cathode electrode positioned on the first light emitting layer;
a bank structure positioned on the auxiliary electrode and defining a second opening, the bank structure comprising a first bank layer, a second bank layer, and a third bank layer which are sequentially stacked; and
a first encapsulation layer positioned on the bank structure,
wherein:
a cavity is formed between the second bank layer and a first side surface of the first bank layer facing the light emitting area in a region overlapping the non-light emitting area,
in a region overlapping the cavity, the first cathode electrode is in contact with the auxiliary electrode, and
the first light emitting layer does not overlap the cavity.

2. The display device of claim 1, wherein:
the second bank layer comprises a second side surface facing the light emitting area, and
the second side surface protrudes further toward the light emitting area than the first side surface of the first bank layer.

3. The display device of claim 2, wherein:
the third bank layer comprises a tip that protrudes further toward the light emitting area than the second side surface of the second bank layer, and
the protruding tip of the third bank layer and the second side surface form an undercut.

4. The display device of claim 1, wherein a width of the cavity in a direction parallel to the substrate is more than twice a height of the first bank layer.

5. The display device of claim 4, wherein a height of the second bank layer is more than twice the height of the first bank layer.

6. The display device of claim 5, wherein the height of the first bank layer ranges from 500 angstroms to 2000 angstroms.

7. The display device of claim 1, wherein a material comprised in the first bank layer, a material comprised in the second bank layer, and a material comprised in the third bank layer differ from one another.

8. The display device of claim 7, wherein:
the first bank layer comprises at least one of silicon nitride or aluminum, and
the second bank layer comprises silicon oxide.

9. The display device of claim 1, further comprising a residual electrode pattern positioned on a second side surface of the second bank layer, wherein the residual electrode pattern comprises a same material as the first cathode electrode and is spaced apart from the first cathode electrode.

10. The display device of claim 9, wherein:
the second side surface comprises a first portion in contact with the residual electrode pattern and a second portion in contact with the first encapsulation layer, and
the second side surface is completely covered by the first portion and the second portion.

11. The display device of claim 10, wherein an area of the second portion is greater than an area of the first portion.

12. The display device of claim 1, wherein the first encapsulation layer is in contact with the first cathode electrode at a portion of the first cathode electrode overlapping the cavity.

13. The display device of claim 9, further comprising:
an organic pattern positioned on the third bank layer, wherein the organic pattern comprises a same material as the first light emitting layer and is spaced apart from the first light emitting layer; and
an electrode pattern positioned on the organic pattern, wherein the electrode pattern comprises a same material as the first cathode electrode and is spaced apart from the first cathode electrode,
wherein the electrode pattern and the residual electrode pattern comprise a same material.

14. The display device of claim 13, wherein the first encapsulation layer is in contact with the organic pattern and the electrode pattern.

15. The display device of claim 1, wherein:
the pixel defining layer is completely covered by the first light emitting layer in a plan view, and
the second opening completely surrounds the first opening in the plan view.

16. The display device of claim 1, further comprising:
a second anode electrode spaced apart from the first anode electrode with the auxiliary electrode interposed between the first anode electrode and the second anode electrode;
a second light emitting layer on the second anode electrode; and
a second cathode electrode on the second light emitting layer,
wherein:
the auxiliary electrode comprises a first side surface facing the bank structure,
the first side surface of the auxiliary electrode comprises a first portion in contact with the first cathode electrode, a second portion in contact with the second cathode electrode, and a third portion in contact with the first bank layer, and
the first portion does not overlap the first light emitting layer, and the second portion does not overlap the second light emitting layer.

17. The display device of claim 16, wherein:
the first portion and the second portion are spaced apart from each other with the third portion interposed between the first portion and the second portion, and
the first cathode electrode and the second cathode electrode are electrically connected through the auxiliary electrode.

18. The display device of claim 17, wherein:
the first encapsulation layer comprises a first inorganic layer on the first cathode electrode and a second inorganic layer on the second cathode electrode, and
in a direction perpendicular to the substrate, the first inorganic layer overlaps the first portion, and the second inorganic layer overlaps the second portion.

19. The display device of claim 18, wherein:
the first inorganic layer and the second inorganic layer are in contact with the second bank layer and the third bank layer, and
the first inorganic layer and the second inorganic layer are spaced apart from each other in a region overlapping the non-light emitting area.

20. A method of fabricating a display device, the method comprising:
forming a substrate comprising a light emitting area and a non-light emitting area, an anode electrode on the light emitting area of the substrate, and an auxiliary electrode on the non-light emitting area of the substrate;
forming a pixel defining layer between the anode electrode and the auxiliary electrode;
forming a first bank material layer, a second bank material layer, and a third bank material layer entirely covering the auxiliary electrode and the pixel defining layer;
forming a photoresist exposing the anode electrode and an overlapping portion around the anode electrode;
performing a first etching process, wherein the first etching process removes the first bank material layer, the second bank material layer, and the third bank material layer in a portion where the photoresist is not formed, forms a hole in a portion overlapping the anode electrode, and forms the third bank material layer as a third bank layer;
performing a second etching process, wherein the second etching process forms a first bank layer and a second bank layer by partially etching an inside of the first bank material layer and the second bank material layer in a portion overlapping the hole, such that a side surface of the second bank material layer protrudes further toward the hole than a side surface of the first bank material layer and the third bank layer has a tip that protrudes further toward the hole than the side surface of the second bank material layer; and
forming an organic pattern, an electrode pattern, and a first inorganic layer positioned on the third bank layer and a light emitting element by:
forming a light emitting layer, a cathode electrode, and a first encapsulation layer on the anode electrode and the third bank layer,
forming a hard mask on the anode electrode and an overlapping portion around the anode electrode, and
performing an etching process removing the light emitting layer, the cathode electrode, and the first encapsulation layer positioned in a portion where the hard mask is not formed,
wherein:
the forming of the first bank layer and the second bank layer forms a cavity between a side surface of the first bank layer facing the light emitting area and the second bank layer, and
the cathode electrode is in contact with the auxiliary electrode in a portion overlapping the cavity.
